(19) United States
(12) Patent Application Publication
(10) Pub. No.: US 2011/0198711 A1
(43) Pub. Date: Aug. 18, 2011

(54) SYSTEM AND METHOD FOR AN INTEGRATED ELECTRONIC AND OPTICAL MEMS BASED SENSOR

(76) Inventors: Ivan Padron, Carteret, NJ (US); Nuggehalli Ravindra, Summit, NJ (US)

(21) Appl. No.: 12/705,591

(22) Filed: Feb. 13, 2010

(51) Int. Cl. H01L 29/84; H01L 29/66; H01L 29/82; H01L 21/02

(52) U.S. Cl. 257/415; 257/414; 257/421; 438/53; 257/E29.324; 257/E29.323; 257/E29.166; 257/E21.002

(57) ABSTRACT

This patent discloses an integrated electronic and optical MEMS (micro-electro-mechanical systems) based sensor wherein the same embossed diaphragm is used as the sensing element of both integrated parts. The optical part of the sensor is based on a Fabry-Perot cavity and the electronic part of the sensor is based on the piezoresistive effect. The signal output obtained from the electronic part of the sensor will be used to assist the fabrication of the Fabry-Perot cavities and as a reference to establish the quiescence point (Q-point) of the signal output from the optical part of the sensor. The invention includes sensors for detecting mechanical movements, such as those caused by pressure, sound, magnetic fields, temperature, chemical reaction or biological activities.

### FIELD OF THE INVENTION

The field of the invention includes sensors for detecting mechanical movements, such as caused by pressure, sound, magnetic fields, chemical reaction or biological activities.

Methods for detecting the mechanical movements that are relevant to this invention are based on Fabry-Perot interferometry and the piezoresistive effect.

### BACKGROUND OF THE INVENTION

In the application of Fabry-Perot interferometry, the sensing element utilizes an optical cavity where interference of multiple reflections changes with movement of cavity surfaces caused by pressure, sound, chemical reaction or biological activities.

In the application of the piezoresistive effect, a change in electrical resistivity of a sensor material is caused by the application of mechanical stress, which is detected, for example, by a Wheatstone bridge circuit.

In the application of the integrated optical and electronic sensor, a same embossed diaphragm is used as the sensing elements for both parts of the sensor.

### SUMMARY OF THE INVENTION

The present invention discloses a method of combining two principles of measurements into one integrated unit with optical and electronic parts, namely Fabry-Perot interferometry and piezoresistivity, to detect movement of the sensing element, which is the moving component of the sensor, and to fabricate Fabry-Perot cavities with the assistance of the piezoresitive part of the sensor.

### BRIEF DESCRIPTION OF THE DRAWINGS

So that those having ordinary skill in the art will have a better understanding of how to make and use the disclosed systems and methods, reference is made to the accompanying figures wherein:

FIG. 1 is a drawing illustrating the sensor configuration of an integrated electronic and optical MEMS based sensor;

FIG. 2 is a drawing illustration of integrated electronic and optical MEMS based sensor header with an incorporated input chamber; and

FIG. 3 is a drawing illustrating the method of fabrication of the Fabry-Perot cavities with the assistance of the piezoresistive part of the sensor.

FIG. 4 is a drawing illustration of a specific application of the integrated electronic and optical MEMS based sensor to measure and detect magnetic fields.

### DETAILED DESCRIPTION OF THE INVENTION

The following is a detailed description of the invention provided to aid those skilled in the art in practicing the present invention. Those of ordinary skill in the art may make modifications and variations in the embodiments described herein without departing from the spirit or scope of the present invention. Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting the invention. All publications, patent applications, patents, figures and other references mentioned herein are expressly incorporated by reference in their entirety.

The integrated sensor can be fabricated with MEMS technology. In one embodiment, the sensor contains a diaphragm with a center rigid body, denoted as an embossed diaphragm, which is used as the sensing element for both the optical and electronic parts of the sensor.

The electronic part of the sensor, which is a piezoresistive based sensor, is fabricated with piezoresistors in a Wheatstone bridge configuration. The optical part of the sensor, which is a Fabry-Perot based sensor, contains an optical cavity formed by the center rigid body and a single mode fiber.

The embossed diaphragm together with MEMS technology allows minimizing the Fabry-Perot gap between the diaphragm and the fiber, and thus avoiding misalignment between the fiber and the diaphragm as well as minimizing the back pressure within the cavity.

The output signals from both parts of the sensor can be used independently of each other, as verification of the measured magnitude, and as a mechanism of back-up in continuous monitoring systems.

The signal output obtained from the electronic part of the sensor will be used to assist the fabrication of the Fabry-Perot cavities and as a reference to establish the quiescence point (Q-point) of the signal output from the optical part of the sensor.

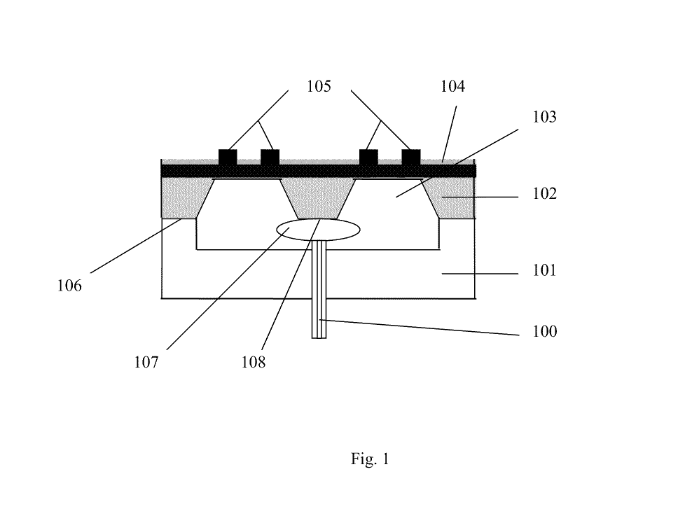

FIG. 1 illustrates the sensor configuration, comprising an optical fiber 100 bonded to an optical fiber support 101. Region 107 denotes the Fabry-Perot cavity formed by one end of the fiber 100 and a second parallel surface that is the boss surface 108 of the embossed diaphragm 102. Optical fiber support 101 is joined to embossed diaphragm 102 at bounding interfaces 106. Piezoresistors 105 are formed upon insulator layer 104, which is formed upon the embossed diaphragm 102, and are aligned to the thin areas of the diaphragm. Region 103 forms the reference pressure chamber.

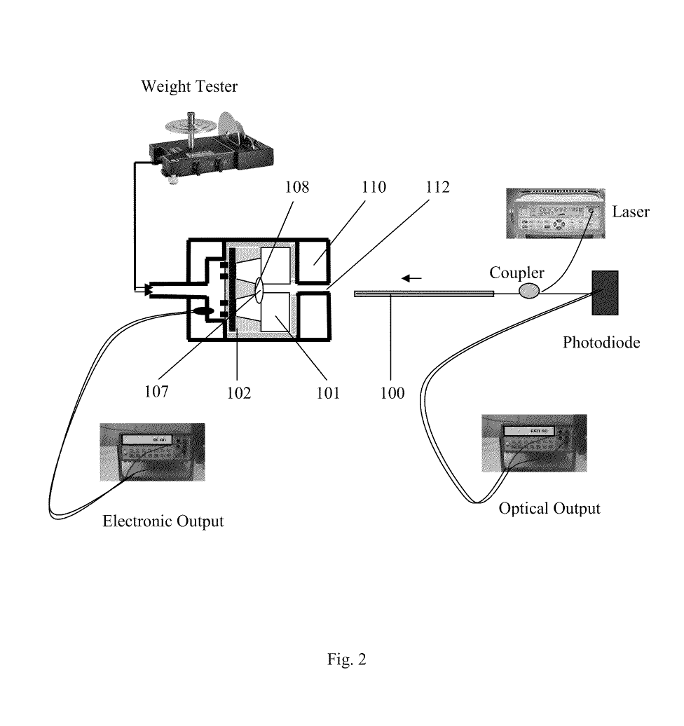

FIG. 2 illustrates a method of fabrication of Fabry-Perot cavities with the assistance of the piesoresistive part of the sensor, for a desired dimension for the gap in the Fabry-Perot cavity 107; a corresponding pressure from the weight tester is applied to deflect the diaphragm by that dimension. The value of that pressure is determined by monitoring the electronic output of the sensor, using a meter. The optical fiber 100 is then introduced through the port 112 (which goes through the sensor packing 110 and the fiber support 101) facing the embossment surface 108. When the tip of the optical fiber 100 reaches the embossed surface 108 and is in contact with it, the electronic output begins to decrease in magnitude as a result of the back pressure from the fiber tip on the embossed diaphragm 102. At this point, the position of the optical fiber 100 can be fixed. When setup pressure is released, the Fabry-Perot part of the sensor has the well defined cavity 107. The optical output is obtained from a meter after the laser signal comes out of the Fabry-Perot cavity and goes through an optical coupler to a photodiode to be converted to an electronic signal.

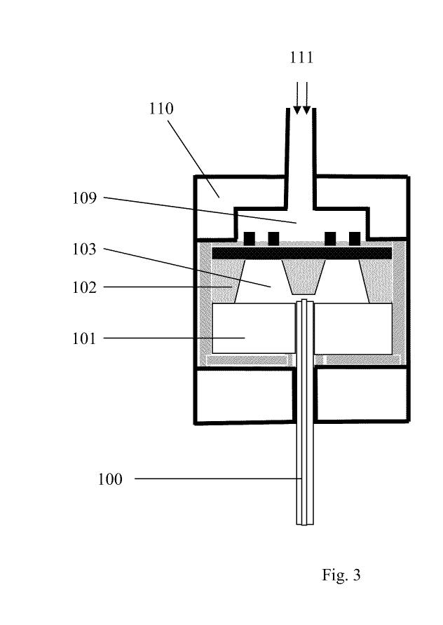

FIG. 3 illustrates the integrated sensor where an input chamber 109 is formed by the sensor configuration of FIG. 1 and enclosure as part of the sensor packing 110 with an input opening. The measurement quantity 111 enters the input chamber 109 thereby changing the interior pressure. Pressure difference between the input chamber 109 and reference chamber 103 causes the embossed diaphragm 102 to move relative to the optical fiber support 101 and optical fiber 100. Movement of the diaphragm changes two things: (1) The Fabry-Perot cavity gap width and (2) the resistances of the piezoresistors.

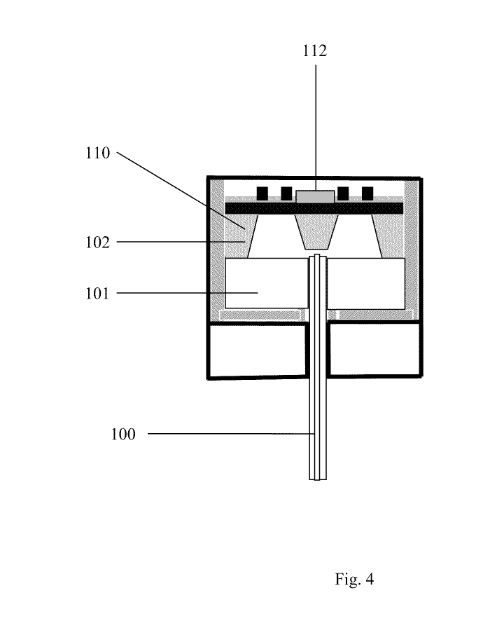

FIG. 4 illustrates the integrated sensor adapted to measure and detect magnetic fields where a soft or hard magnetic coating 112 is deposited on the silicon diaphragm. The sensor packing is modified from FIG. 3. The external magnetic field causes the embossed diaphragm 102 to move relative to the optical fiber support 101 and optical fiber 100.

Although the systems and methods of the present disclosure have been described with reference to exemplary embodiments thereof, the present disclosure is not limited thereby. Indeed, the exemplary embodiments are implementations of the disclosed systems and methods are provided for illustrative and non-limitative purposes. Changes, modifications, enhancements and/or refinements to the disclosed systems and methods may be made without departing from the spirit or scope of the present disclosure. Accordingly, such changes, modifications, enhancements and/or refinements are encompassed within the scope of the present invention.

We claim:

1. An Integrated Electronic and Optical MEMS based sensor.

2. The sensor of claim 1, wherein the electronic part is a piezoresistive based sensor and the optical part is a Fabry-Perot base sensor.

3. The sensor of claim 1, wherein the same embossed diaphragm is used as the sensing element of a Fabry-Perot based sensor and a Piezoresistive based sensor.

4. A method of fabrication of the sensor of claim 1, wherein the Fabry-Perot part of the sensor is assisted from the piezoresistive part of the sensor.

5. The sensor of claim 1, wherein partially deposited magnetic layer over the embossed diaphragm is used as the sensing element of a Fabry-Perot based sensor.

6. The sensor of claim 1, wherein the partially deposited magnetic layer over the embossed diaphragm will respond to external magnetic field.

7. The sensor of claim 1, wherein the sensing element consisting of crystalline or non-crystalline semiconductor material, inorganic crystal, metals, or combinations thereof.

8. The sensor of claim 1, that can be used for measurement or detection of changing of the magnetic field.

9. The sensor of claim 1, that can be used for dynamic and static sensing separately or in combination.

10. The sensor of claim 1, wherein the sensing element is receptive to low dynamic pressures in the presence of high static pressures.

11. An array sensing system of sensors claimed in claim 1.

12. The sensor of claim 1, wherein the sensing element is receptive to at least one of acoustical vibration, mechanical vibration, pressure, temperature, a magnetic field, or combinations thereof.

13. A temperature sensing system of sensor claimed in 1, wherein the sensing element is receptive to temperature, the sensing unit being configured to transmit an optical signal in response to temperature.

14. A pressure sensing system of sensor claimed in 1, wherein the diaphragm is receptive to pressure, the sensing unit being configured to transmit an optical signal in response to pressure.

15. A chemical sensing system of sensor claimed in 1, wherein the diaphragm is configured to be receptive to chemical reaction on the diaphragm surface, the sensing unit being configured to transmit an optical signal in response to chemical reaction.

16. A vibration sensing system of sensor claimed in 1, wherein the diaphragm is configured to be receptive to vibration (acoustical or mechanic), the sensing unit being configured to transmit an optical signal in response to vibration.

17. A magnetic field sensing system of sensor claimed in 1, wherein the diaphragm is configured to be receptive to magnetic field, the sensing unit being configured to transmit an optical signal in response to magnetic field.

18. A method of Q-point stabilization of the Fabry-Perot Sensor.

19. A method of fabrication of integrated MEMS based sensor of claim 1.

20. A sensor system wherein the integrated sensor of claim 1 is used as a backup with integration redundancy.
